(19) United States
(12) Patent Application Publication
(10) Pub. No.: US 2015/0188060 A1
(43) Pub. Date: Jul. 2, 2015

(54) ORGANOMETALLIC COMPOUNDS AND ORGANIC ELECTROLUMINESCENCE DEVICES EMPLOYING THE SAME

(71) Applicants: INDUSTRIAL TECHNOLOGY RESEARCH INSTITUTE, Hsinchu (TW); Ritdisplay Corporation, Hukou Township (TW)

(72) Inventors: Teng-Chih CHAO, Hsinchu City (TW); Meng-Hao CHANG, New Taipei City (TW); Han-Cheng YEH, Taipei City (TW); Ching-Hui CHOU, Hsinchu City (TW)

(73) Assignees: INDUSTRIAL TECHNOLOGY RESEARCH INSTITUTE, Hsinchu (TW); Ritdisplay Corporation, Hukou Township (TW)

(21) Appl. No.: 14/279,987

(22) Filed: May 16, 2014

(30) Foreign Application Priority Data
Dec. 26, 2013 (TW) 102148378

(51) Int. Cl. H01L 51/00; C07F 15/00; H01L 51/50

(52) U.S. Cl. CPC H01L 51/0085; H01L 51/5012; C07F 15/0033

(57) ABSTRACT

Organometallic compounds and organic electroluminescence devices employing the same are provided. The organometallic compound has a chemical structure as represented by

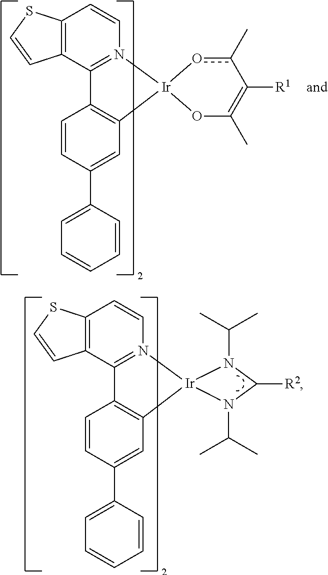

wherein R¹, R² are hydrogen, phenyl, biphenyl, diisopropyl amino, or derivatives thereof. The organic electroluminescence device includes a pair of electrodes and an electroluminescent element disposed between the pair of electrodes, wherein the electroluminescent element includes the organometallic compound.

### CROSS REFERENCE TO RELATED APPLICATIONS

This application claims priority of Taiwan Patent Application No. 102148378, filed on Dec. 26, 2013, the entirety of which is incorporated by reference herein. The subject matter of this application relates to that of copending application filed May 16, 2014 for “ORGANIC METAL COMPLEXES AND ORGANIC ELECTROLUMINESCENT DEVICES COMPRISING THE SAME” by Teng-Chih Chao, Meng-Hao Chang, Han-Cheng Yeh and Ching-Hui Chou. The disclosure of the copending application is incorporated herein by reference in their entirety.

### TECHNICAL FIELD

The technical field relates to an organometallic compound and an organic electroluminescence device employing the same.

### BACKGROUND

Organic electroluminescent devices have superior characteristics, such as low driving voltage (e.g., 10V or less), broad viewing angle, rapid response time and high contrast, over liquid crystal displays (LCDs), plasma display panels (PDPs) and inorganic electroluminescent display devices. Based on these advantages, organic electroluminescent devices can be used as pixels of graphic displays, television image displays and surface light sources. In addition, organic electroluminescent devices can be fabricated on transparent flexible substrates, which can reduce the thickness and weight thereof and have good color representation. Therefore, in recent years, organic electroluminescent devices have gradually been used in flat panel displays (FPDs).

A representative organic electroluminescent device was reported by Gurnee in 1969 (U.S. Pat. Nos. 3,172,862 and 3,173,050). However, this organic electroluminescent device suffers from limitations in its applications because of its limited performance. Since Eastman Kodak Co. reported multilayer organic electroluminescent devices capable of overcoming the problems of the prior art devices in 1987, remarkable progress has been made in the development of the organic electroluminescent technique.

Such organic electroluminescent devices comprise a first electrode as a hole injection electrode (anode), a second electrode as an electron injection electrode (cathode), and an organic light-emitting layer disposed between the cathode and the anode, wherein holes injected from the anode and electrons injected from the cathode combine with each other in the organic light-emitting layer to form electron-hole pairs (excitons), and then the excitons fall from the excited state to the ground state and decay to emit light. At this time, the excitons may fall from the excited state to the ground state via the singlet excited state to emit light (i.e. fluorescence), or the excitons may fall from the excited state to the ground state via the triplet excited state to emit light (i.e. phosphorescence). In the case of fluorescence, the probability of the singlet excited state is 25% and thus the luminescence efficiency of the devices is limited. In contrast, phosphorescence can utilize both probabilities of the triplet excited state (75%) and the singlet excited state (25%), and thus the theoretical internal quantum efficiency may reach 100%. Therefore, it is crucial to develop highly efficient phosphorescent material, in order to increase the emissive efficiency of an organic electroluminescent device.

Currently, the main luminescent materials of the organic electroluminescent devices are small-molecule materials due to higher efficiency, brightness and life-span of the small-molecule organic electroluminescent devices than the polymer light-emitting diodes (PLEDs). A small-molecule organic electroluminescent device is mainly fabricated by way of vacuum evaporation rather than spin coating or inkjet printing like PLEDs. However, the equipment cost of the vacuum evaporation is high. Additionally, 95% of the organic electroluminescent materials are deposited on the chamber wall of the manufacturing equipment, such that only 5% of the organic electroluminescent materials are coated on a substrate, resulting in high manufacturing cost. Therefore, a wet process (such as spin coating or blade coating) has been provided to fabricate small-molecule organic electroluminescent devices to reduce equipment costs and improve utilization rate of organic electroluminescent materials.

Therefore, for the organic electroluminescent technique, it is necessary to develop soluble organic phosphorescent materials which are suitable for use in a wet process.

### SUMMARY

An exemplary embodiment of an organometallic compound has formula (I) or (II), of:

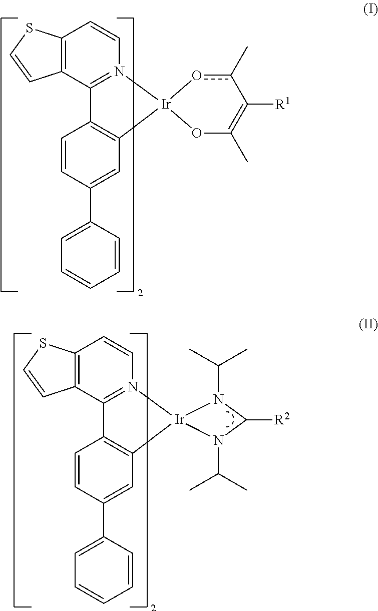

In formula (I) and (II), R¹, R² are hydrogen, phenyl, biphenyl, diisopropyl amino, or derivatives thereof.

In another exemplary embodiment of the disclosure, an organic electroluminescent device is provided. The device includes a pair of electrodes and an electroluminescent element disposed between the pair of electrodes, wherein the electroluminescent element includes the aforementioned organometallic compound (serving as a reddish orange or red phosphorescence dopant material).

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows a cross-sectional view of an organic electroluminescent device disclosed by an embodiment of the disclosure.

### DETAILED DESCRIPTION

The following description is of the best-contemplated mode of carrying out the disclosure. This description is made for the purpose of illustrating the general principles of the disclosure and should not be taken in a limiting sense. The scope of the disclosure is best determined by reference to the appended claims.

Organometallic Compounds

The disclosure provides an organometallic compound having a structure represented by formula (I) or (II):

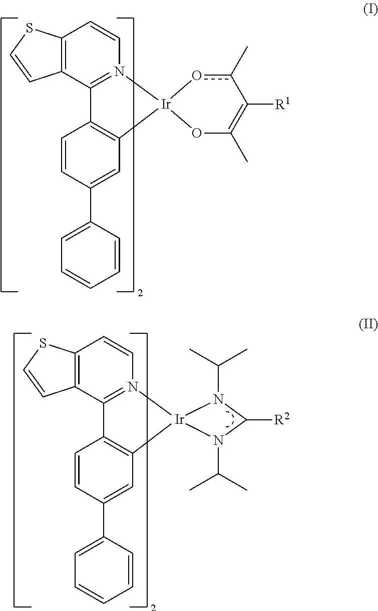

In formula (I) and (II), R¹, R² may be hydrogen, phenyl, biphenyl, diisopropyl amino, or derivatives thereof.

The organometallic compounds according to formula (I) or (II) of the disclosure include the following compounds, as shown in Table 1. In addition, the contraction thereof are also named and shown in Table 1.

TABLE 1

| Examples | Compound structure | Contraction |
|---|---|---|
| 1 | 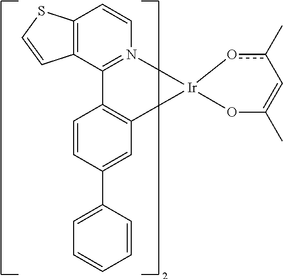 | PO-01-Bp |
| 2 | 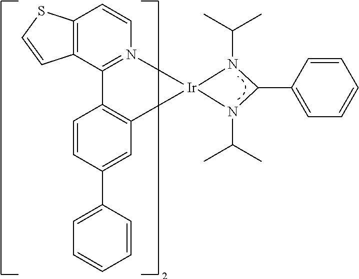 | PO-01-Bp-dipba |
| 3 | 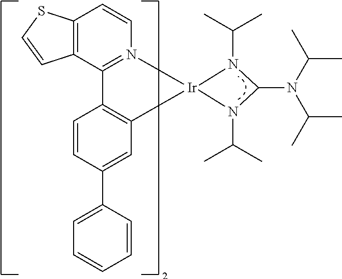 | PO-01-Bp-dipig |

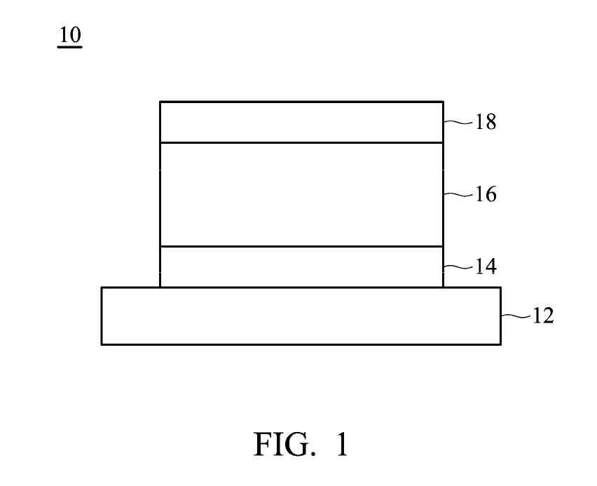

FIG. 1 shows a cross-sectional view of an embodiment of an organic electroluminescent device 10. The organic electroluminescent device 10 includes a substrate 12, a bottom electrode 14, an electroluminescent element 16, and a top electrode 18, as shown in FIG. 1. The organic electroluminescent device may be top-emission, bottom-emission, or dual-emission organic electroluminescent device. The substrate 12 may be a glass, plastic, or semiconductor substrate. Suitable materials for the bottom electrode 14 and the top electrode 18 may be Li, Mg, Ca, Al, Ag, In, Au, W, Ni, Pt, Cu, indium tin oxide (ITO), indium zinc oxide (IZO), aluminum zinc oxide (AZO), zinc oxide (ZnO) or combinations thereof, formed by thermal evaporation, sputtering, or plasma enhanced chemical vapor deposition. Furthermore, at least one of the bottom electrode 14 and the top electrode 18 is transparent.

The electroluminescent element 16 includes at least one emission layer, and may further include a hole injection layer, a hole transport layer, an electron transport layer, an electron injection layer or other layers. Specifically, in accordance with an embodiment of the disclosure, the electroluminescent element 16 includes organometallic compounds having formula (I) or (II). That is, in the electroluminescent element 16, at least one layer includes the aforementioned organometallic compounds.

According to another embodiment of the disclosure, the organic electroluminescent device 10 may be a phosphorescent organic electroluminescent device, and the phosphorescent electroluminescent element includes a host material and a phosphorescent dopant material. The phosphorescent dopant material includes the aforementioned organometallic compounds having formula (I) or (II). One of ordinary skill in the art may dope the required phosphorescent dopant materials with the disclosed organometallic compounds and alter the doping amount of the adopted dopants based on the used organic electroluminescent material and the required characteristics of the device. Therefore, the doping amount of the dopants is neither related to the characteristic of the invention nor the base of limiting the scope of the invention. For instance, while adopting the organometallic compound having formula (I) as a dopant in the emission layer, the doping amount of the organometallic compound having formula (I) may be between 0.1% to 15% based on the weight of the host material.

One of ordinary skill in the art may dope the disclosed organometallic compounds with the required phosphorescent dopant materials and alter the doping amount of the adopted dopants based on the used organic electroluminescent material and the required characteristics of the device. Therefore, the doping amount of the dopants is neither related to the characteristic of the invention nor the base of limiting the scope of the invention.

In order to clearly disclose the organic electroluminescent devices of the disclosure, the following examples (employing the organometallic compounds of Example 1 serving as dopant) are intended to illustrate the disclosure more fully without limiting their scope, since numerous modifications and variations will be apparent to those skilled in this art.

### Example 1

### Preparation of the Organometallic Compound (PO-01-Bp)

Step 1:

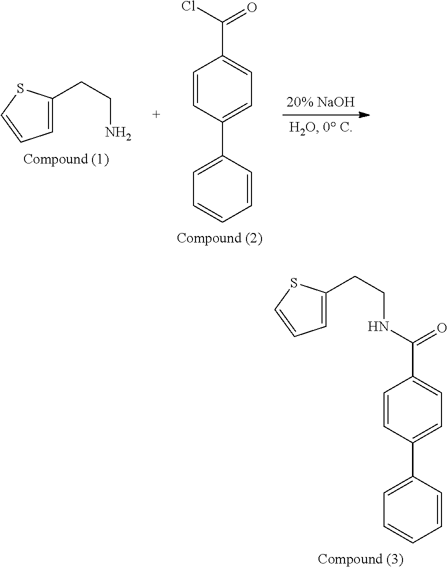 [SMILES: NCCc1cccs1 ; O=C(Cl)c1ccc(-c2ccccc2)cc1 ; O=C(NCCc1cccs1)c1ccc(-c2ccccc2)cc1]

Compound (2) (4-phenyl benzoyl chloride, 25 g, 115.47 mmol) and 150 mL H₂O were added into a 500 mL single-neck bottle with an addition funnel. Next, compound (1) (2-(2-aminoethyl)thiophene, 17.63 g, 138.56 mmol, 1.2 eq.) was added dropwisely into the bottle via the addition funnel under ice-bath cooling. White solid was gradually formed. After dropping, a NaOH aqueous solution (20%) was added into the bottle and stirred overnight. After filtration with a porcelain funnel, a white solid of compound (3) (36 g, yield of 100%) was obtained.

Compound (3) was analyzed by NMR spectroscopy. The spectral information of compound (3) is listed below:

¹H NMR (CDCl₃, 200 MHz) δ 7.79 (d, J=2.0 Hz, 2H), 7.62 (t, J=6.8, 1.8 Hz, 4H), 7.38-7.58 (m, 3H), 7.20 (dd, J=5.2, 1.2 Hz, 1H), 7.00 (d, J=2.0 Hz, 1H), 6.99 (s, 1H), 6.37 (s, 1H), 3.76 (q, J=6.6, 6.2 Hz, 2H), 3.19 (t, J=6.2 Hz, 2H).

Step 2:

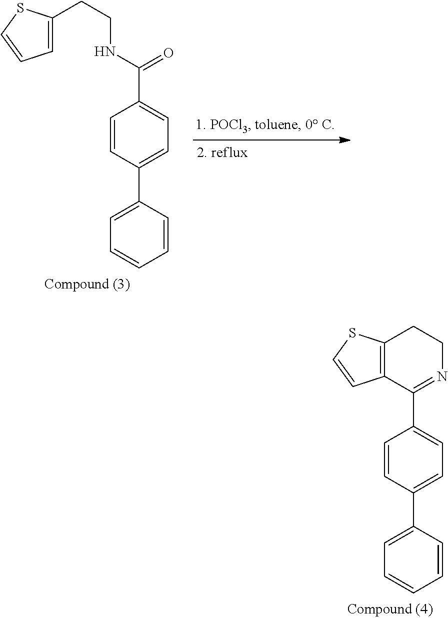 [SMILES: O=C(NCCc1cccs1)c1ccc(-c2ccccc2)cc1 ; c1ccc(-c2ccc(C3=NCCc4sccc43)cc2)cc1]

Compound (3) (12 g, 39 mmol) and toluene (175 mL) were added into a 250 mL single-neck round-bottom flask. POCl₃ (10.9 mL, 117 mmol, 3 eq.) was added dropwisely into the flask via an addition funnel under ice-bath cooling. After dropping, the ice-bath was replaced by an oil bath and heated until toluene reflux. After reaction overnight, a saturated NaHCO₃ aqueous solution was added into the flask for neutralization of the reaction. After toluene extraction, a toluene solution was collected and dried by dried magnesium sulfate. After evaporation and standing for several hours, compound (4) (crystal, 6.7 g) was obtained with a yield of 60%.

Compound (4) was analyzed by NMR spectroscopy. The spectral information of compound (4) is listed below:

¹H NMR (CDCl₃, 200 MHz) δ 7.79 (d, J=2.0 Hz, 2H), 7.66-7.75 (m, 4H), 7.37-7.50 (m, 3H), 7.10 (q, J=5.2, 2.8 Hz, 2H), 3.98 (t, J=8.4 Hz, 2H), 2.95 (t, J=7.6 Hz, 2H).

Step 3:

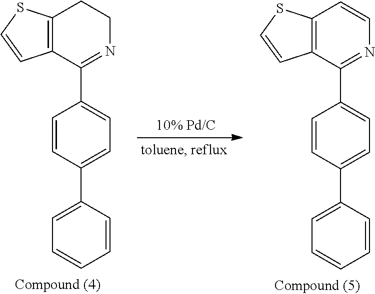 [SMILES: c1ccc(-c2ccc(C3=NCCc4sccc43)cc2)cc1 ; c1ccc(-c2ccc(-c3nccc4sccc34)cc2)cc1]

Compound (4) (6.7 g, 23.2 mmol), toluene (100 mL) and 10% Pd/C (10 g) were added into a 250 mL single-neck round-bottom flask and heated to toluene reflux. After reaction for 48 hrs, the result was filtrated by diatomaceous earth (Celite 545) to remove Pd/C. After the filtrate was concentrated and purified by column chromatography (ethyl acetate/n-hexane=1/5), a pale khaki solid of compound (5) (5 g) was obtained with a yield of 75%.

Compound (5) was analyzed by NMR spectroscopy. The spectral information of compound (5) is listed below:

¹H NMR (CDCl₃, 200 MHz) δ 8.57 (d, J=5.8 Hz, 1H), 7.94 (d, J=8.4 Hz, 2H), 7.67-7.82 (m, 6H), 7.38-7.54 (m, 4H).

Step 4:

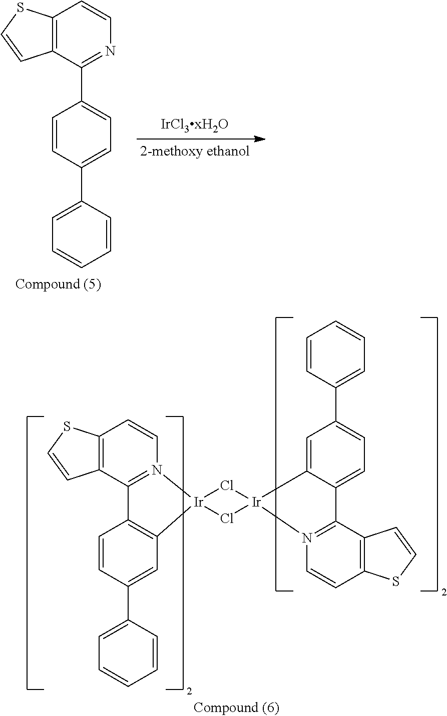

Compound (5) (5.0 g, 17.4 mmol, 2.2 eq.), IrCl₃xH₂O (2.36 g, 7.9 mmol), 2-methoxy ethanol (21 mL), and water (7 mL) were added into a 100 mL single-neck round-bottom flask. After heating to 140° C. and reacting for 24 hrs, the reaction was quenched by adding plenty of water. After filtration, compound (6) (orange solid, 5.5 g) was obtained with a yield of 44%.

Compound (6) was analyzed by NMR spectroscopy. The spectral information of compound (6) is listed below:

¹H NMR (CDCl₃, 200 MHz) δ 9.19 (d, J=6.6 Hz, 4H), 8.38 (d, J=6.0 Hz, 4H), 8.13 (d, J=8.4 Hz, 4H), 7.77 (d, J=5.8 Hz, 4H), 7.08-8.20 (m, 24H), 7.01 (d, J=6.6, 4H), 6.27 (d, J=1.8 Hz, 4H).

Step 5:

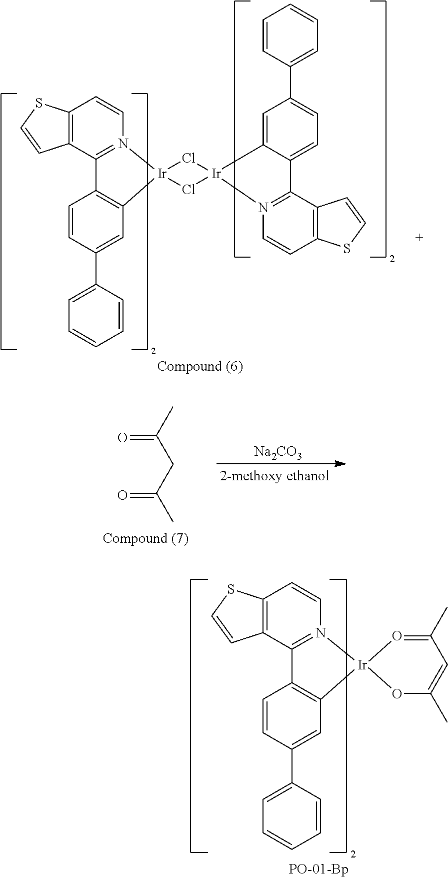

Compound (6) (5.0 g, 3.13 mmol), compound (7) (2,4-pentanedione, 1.25 g, 12.52 mmol, 4 eq.), Na₂CO₃ (1.33 g, 12.52 mmol, 4 eq.), and 2-methoxyethanol (30 mL) were added into a 100 mL single-neck round-bottom flask and heated to 140° C. After reacting for 24 hrs and cooling to room temperature, the result was washed with 50 mL water and filtered to obtain orange solid product. The product was purified by column chromatography with dichloromethane/n-hexane (1/1), obtaining compound (PO-01-Bp) (orange solid powder, 1.35 g) with a yield of 50%.

Compound (PO-01-Bp) was analyzed by NMR spectroscopy. The spectral information of compound (PO-01-Bp) is listed below:

¹H NMR (200 MHz, CDCl₃) δ 8.50 (d, J=6.2 Hz, 2H), 8.37 (d, J=5.6 Hz, 2H), 8.17 (d, J=8.0 Hz, 2H), 7.66-7.71 (m, 4H), 7.01-7.22 (m, 12H), 6.56 (d, J=2.0 Hz, 2H), 5.23 (s, 1H), 1.79 (s, 6H).

### Example 2

### Preparation of the Organometallic Compound (PO-01-Bp-Dipba)

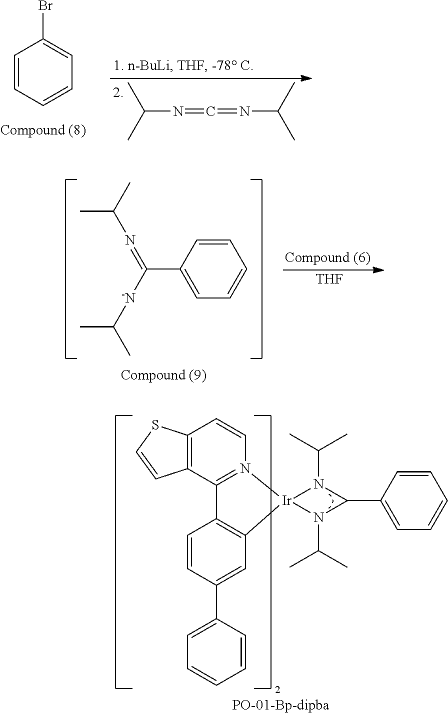

Compound (8) (bromobenzene, 1.45 mL, 13.76 mmol) and distilled THF (50 mL, anhydrous) were added into a 250 mL dual-neck round-bottom flask. After cooling to −78° C., n-BuLi (8.6 mL, 13.76 mmol) was added dropwisely into the flask. After dropping and stirring for 30 minutes, N,N-diisopropylcarbodiimide (2.15 mL, 13.76 mmol) was added dropwisely into the flask under −78° C. After dropping and rapid stirring for 30 minutes, a solution containing compound (9) was obtained. The solution containing compound (9) was dropped into a THF solution (70 mL) containing compound (6) (5.5 g, 3.44 mmol) and heated to reflux. After reaction overnight and removal of solvent, the result was purified by column chromatography with ethyl acetate/n-hexane (1/1), obtaining compound (PO-01-Bp-dipba) (dark red solid, 1.2 g) with a yield of 36%.

Compound (PO-01-Bp-dipba) was analyzed by NMR spectroscopy. The spectral information of compound (PO-01-Bp-dipba) is listed below:

¹H NMR (200 MHz, CDCl₃) δ 9.43 (d, J=6.4 Hz, 2H), 8.38 (d, J=6.0 Hz, 2H), 8.17 (d, J=8.0 Hz, 2H), 7.79 (d, J=6.6 Hz, 2H), 7.70 (d, J=5.6 Hz, 2H), 7.05-7.44 (m, 17H), 6.58 (d, J=1.8, 2H), 3.26 (m, 2H), 0.72 (d, J=6.2 Hz, 6H), −0.09 (d, J=6.2 Hz, 6H).

### Example 3

### Preparation of the Organometallic Compound (PO-01-Bp-Dipig)

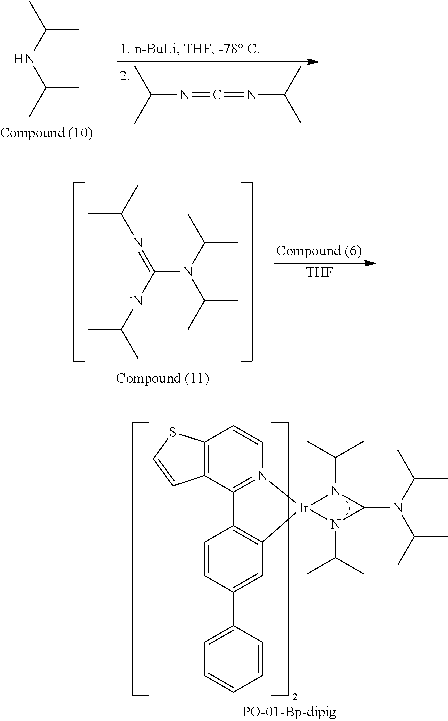

Compound (10) (diisopropylamine, 1.87 mL, 13.24 mmol) and distilled THF (50 mL, anhydrous) were added into a 250 mL dual-neck round-bottom flask. After cooling to −78° C., n-BuLi (8.3 mL, 13.24 mmol) was added dropwisely into the flask. After dropping and stirring for 30 minutes, N,N-diisopropylcarbodiimide (2.1 mL, 13.24 mmol) was added dropwisely into the flask under −78° C. After dropping and rapid stirring for 30 minutes, a solution containing compound (11) was obtained. The solution containing compound (11) was dropped into a THF solution (70 mL) containing compound (6) (5.3 g, 3.31 mmol) and heated to reflux. After reaction overnight and removal of solvent, the result was purified by column chromatography with ethyl acetate/n-hexane (1/1), obtaining compound (PO-01-Bp-dipig) (dark red solid, 1.28 g) with a yield of 40%.

Compound (PO-01-Bp-dipig) was analyzed by NMR spectroscopy. The spectral information of compound (PO-01-Bp-dipig) is listed below:

¹H NMR (200 MHz, CDCl₃) δ 9.23 (d, J=6.2 Hz, 2H), 8.20 (d, J=5.8 Hz, 2H), 8.14 (d, J=7.6 Hz, 2H), 7.60 (d, J=6.6 Hz, 2H), 7.45 (d, J=5.6 Hz, 2H), 7.05-7.40 (m, 12H), 6.48 (s, 2H), 3.81 (m, 2H), 3.54 (m, 2H), 1.23 (t, J=5.0 Hz, 12H), 0.83 (d, J=6.2 Hz, 6H), −0.05 (d, J=5.8 Hz, 6H).

### Organic Electroluminescent Devices

### Example 4

### Preparation of the Organic Electroluminescent Device (1) (Dry Process)

A glass substrate with a patterned indium tin oxide (ITO) film of 150 nm was provided and then washed with a neutral cleaning agent, acetone, and ethanol with ultrasonic agitation. After drying the substrate with a nitrogen flow, the substrate was subjected to a UV/ozone treatment for 30 minutes. Next, PEDOT (poly(3,4)-ethylendioxythiophen) and PSS (e-polystyrenesulfonate) were selected to coat on the ITO film by a spin coating process (with a rotation rate of 2,000 rpm) to form a PEDOT:PSS film (with a thickness of 45 nm, serving as a hole injection layer). After heating to 130° C. for 10 min, a TAPC (di-[4-(N,N-ditolyl-amino)-phenyl]cyclohexane) layer (with a thickness of 35 nm), a TCTA (4,4′,4″-tris(carbazol-9-yl)triphenylamine) layer doped with compound (PO-01-Bp)

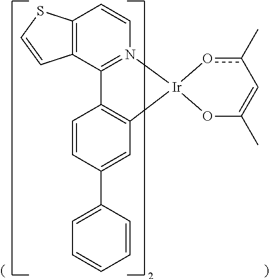

(the ratio between TCTA and compound (PO-01-Bp) was 100:6, with a thickness of 10 nm), a TmPyPB (1,3,5-tri[(3-pyridyl)-phen-3-yl]benzene) layer (with a thickness of 42 nm), a LiF layer (with a thickness of 0.5 nm), and an Al layer (with a thickness of 120 nm) were subsequently deposited on the ITO film under 10⁻⁶ torr and packaged, obtaining the organic electroluminescent device (1). The structure of the organic electroluminescent device (1) is described in the following:

ITO (150 nm)/TAPC (35 nm)/TCTA: compound (PO-01-Bp) (6%, 10 nm)/TmPyPB (42 nm)/LiF (0.5 nm)/Al (120 nm)

The optical properties including brightness (cd/m²), current efficiency (cd/A), power efficiency (1 m/W), emission wavelength (nm), and color coordinates (x, y) of the organic electroluminescent device (1) were measured and the results are described in Table 2.

### Example 5

### Preparation of the Organic Electroluminescent Device (2) (Dry Process)

A glass substrate with a patterned indium tin oxide (ITO) film of 150 nm was provided and then washed with a neutral cleaning agent, acetone, and ethanol with ultrasonic agitation. After drying the substrate with a nitrogen flow, the substrate was subjected to a UV/ozone treatment for 30 minutes. Next, PEDOT (poly(3,4)-ethylendioxythiophen) and PSS (e-polystyrenesulfonate) were selected to coat on the ITO film by a spin coating process (with a rotation rate of 2,000 rpm) to form a PEDOT:PSS film (with a thickness of 45 nm, serving as a hole injection layer). After heating to 130° C. for 10 min, a TAPC (di-[4-(N,N-ditolyl-amino)-phenyl]cyclohexane) layer (with a thickness of 35 nm), a TCTA (4,4′,4″-tris(carbazol-9-yl)triphenylamine) layer doped with compound (PO-01-Bp-dipba)

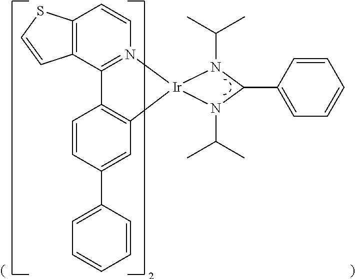

(the ratio between TCTA and compound (PO-01-Bp-dipba) was 100:6, with a thickness of 10 nm), a TmPyPB (1,3,5-tri[(3-pyridyl)-phen-3-yl]benzene) layer (with a thickness of 42 nm), a LiF layer (with a thickness of 0.5 nm), and an Al layer (with a thickness of 120 nm) were subsequently deposited on the ITO film under 10⁻⁶ torr and packaged, obtaining the organic electroluminescent device (2). The structure of the organic electroluminescent device (2) is described in the following:

ITO (150 nm)/TAPC (35 nm)/TCTA: compound (PO-01-Bp-dipba) (6%, 10 nm)/TmPyPB (42 nm)/LiF (0.5 nm)/A1 (120 nm)

The optical properties including brightness (cd/m²), current efficiency (cd/A), power efficiency (1 m/W), emission wavelength (nm), and color coordinates (x, y) of the organic electroluminescent device (2) were measured and the results are described in Table 2.

### Example 6

### Preparation of the Organic Electroluminescent Device (3) (Dry Process)

A glass substrate with a patterned indium tin oxide (ITO) film of 150 nm was provided and then washed with a neutral cleaning agent, acetone, and ethanol with ultrasonic agitation. After drying the substrate with a nitrogen flow, the substrate was subjected to a UV/ozone treatment for 30 minutes. Next, PEDOT (poly(3,4)-ethylendioxythiophen) and PSS (e-polystyrenesulfonate) were selected to coat on the ITO film by a spin coating process (with a rotation rate of 2,000 rpm) to form a PEDOT:PSS film (with a thickness of 45 nm, serving as a hole injection layer). After heating to 130° C. for 10 min, a TAPC (di-[4-(N,N-ditolyl-amino)-phenyl]cyclohexane) layer (with a thickness of 35 nm), a TCTA (4,4′,4″-tris(carbazol-9-yl)triphenylamine) layer doped with compound (PO-01-Bp-dipig)

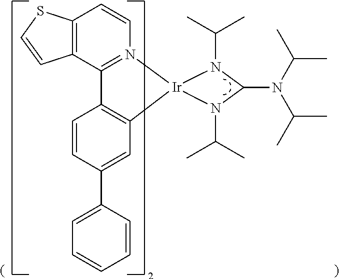

(the ratio between TCTA and compound (PO-01-Bp-dipig) was 100:6, with a thickness of 10 nm), a TmPyPB (1,3,5-tri[(3-pyridyl)-phen-3-yl]benzene) layer (with a thickness of 42 nm), a LiF layer (with a thickness of 0.5 nm), and an Al layer (with a thickness of 120 nm) were subsequently deposited on the ITO film under 10⁻⁶ torr and packaged, obtaining the organic electroluminescent device (3). The structure of the organic electroluminescent device (3) is described in the following:

ITO (150 nm)/TAPC (35 nm)/TCTA: compound (PO-01-Bp-dipig) (6%, 10 nm)/TmPyPB (42 nm)/LiF (0.5 nm)/Al (120 nm)

The optical properties including brightness (cd/m²), current efficiency (cd/A), power efficiency (1 m/W), emission wavelength (nm), and color coordinates (x, y) of the organic electroluminescent device (3) were measured and the results are described in Table 2.

### Example 7

### Preparation of the Organic Electroluminescent Device (4) (Wet Process)

A glass substrate with a patterned indium tin oxide (ITO) film of 150 nm was provided and then washed with a neutral cleaning agent, acetone, and ethanol with ultrasonic agitation. After drying the substrate with a nitrogen flow, the substrate was subjected to a UV/ozone treatment for 30 minutes. Next, PEDOT (poly(3,4)-ethylendioxythiophen) and PSS (e-polystyrenesulfonate) were selected to coat on the ITO film by a spin coating process (with a rotation rate of 2,000 rpm) to form a PEDOT:PSS film (with a thickness of 45 nm, serving as a hole injection layer). After heating to 130° C. for 10 min, a light-emitting film (with a thickness of 30 nm) was formed on the PEDOT:PSS film by a spin coating process. The composition of the light-emitting film included TCTA (4,4′,4″-tris(carbazol-9-yl)triphenylamine) and compound (PO-01-Bp)

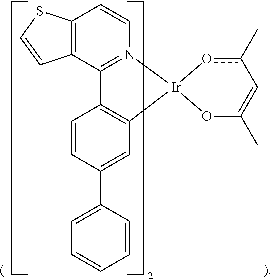

TCTA and compound (PO-01-Bp) (the weight ratio between TCTA and compound (PO-01-Bp) was 94:6) were dissolved in chlorobenzene to prepare the light-emitting film. Next, a TmPyPB (1,3,5-tri[(3-pyridyl)-phen-3-yl]benzene) layer (with a thickness of 55 nm, serving as a hole-block/electron-transport layer) was deposited on the light-emitting film. Next, a LiF layer (with a thickness of 1 nm) and an Al layer (with a thickness of 100 nm) were subsequently deposited on the TmPyPB film and packaged, obtaining the organic electroluminescent device (4). The structure of the organic electroluminescent device (4) is described in the following:

ITO (150 nm)/PEDOT:PSS (45 nm)/TCTA: compound (PO-01-Bp) (30 nm)/TmPyPB (55 nm)/LiF (1 nm)/A1 (100 nm)

The optical properties including brightness (cd/m²), current efficiency (cd/A), power efficiency (1 m/W), emission wavelength (nm), and color coordinates (x, y) of the organic electroluminescent device (4) were measured and the results are described in Table 2.

### Example 8

### Preparation of the Organic Electroluminescent Device (5) (Wet Process)

A glass substrate with a patterned indium tin oxide (ITO) film of 150 nm was provided and then washed with a neutral cleaning agent, acetone, and ethanol with ultrasonic agitation. After drying the substrate with a nitrogen flow, the substrate was subjected to a UV/ozone treatment for 30 minutes. Next, PEDOT (poly(3,4)-ethylendioxythiophen) and PSS (e-polystyrenesulfonate) were selected to coat on the ITO film by a spin coating process (with a rotation rate of 2,000 rpm) to form a PEDOT:PSS film (with a thickness of 45 nm, serving as a hole injection layer). After heating to 130° C. for 10 min, a light-emitting film (with a thickness of 30 nm) was formed on the PEDOT:PSS film by a spin coating process. The composition of the light-emitting film included NPB (N,N′-bis(naphthalen-1-yl)-N,N′-bis(phenyl)-benzidine) and compound (PO-01-Bp-dipba)

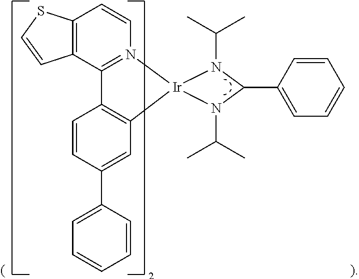

NPB and compound (PO-01-Bp-dipba) (the weight ratio between NPB and compound (PO-01-Bp-dipba) was 95:5) were dissolved in chlorobenzene to prepare the light-emitting film. Next, a TmPyPB (1,3,5-tri[(3-pyridyl)-phen-3-yl]benzene) layer (with a thickness of 55 nm, serving as a hole-block/electron-transport layer) was deposited on the light-emitting film. Next, a LiF layer (with a thickness of 1 nm) and an Al layer (with a thickness of 100 nm) were subsequently deposited on the TmPyPB film and packaged, obtaining the organic electroluminescent device (5). The structure of the organic electroluminescent device (5) is described in the following:

ITO (150 nm)/PEDOT:PSS (45 nm)/NPB: compound (PO-01-Bp-dipba) (30 nm)/TmPyPB (55 nm)/LiF (1 nm)/A1 (100 nm)

The optical properties including brightness (cd/m²), current efficiency (cd/A), power efficiency (1 m/W), emission wavelength (nm), and color coordinates (x, y) of the organic electroluminescent device (5) were measured and the results are described in Table 2.

### Example 9

### Preparation of the Organic Electroluminescent Device (6) (Wet Process)

A glass substrate with a patterned indium tin oxide (ITO) film of 150 nm was provided and then washed with a neutral cleaning agent, acetone, and ethanol with ultrasonic agitation. After drying the substrate with a nitrogen flow, the substrate was subjected to a UV/ozone treatment for 30 minutes. Next, PEDOT (poly(3,4)-ethylendioxythiophen) and PSS (e-polystyrenesulfonate) were selected to coat on the ITO film by a spin coating process (with a rotation rate of 2,000 rpm) to form a PEDOT:PSS film (with a thickness of 45 nm, serving as a hole injection layer). After heating to 130° C. for 10 min, a light-emitting film (with a thickness of 30 nm) was formed on the PEDOT:PSS film by a spin coating process. The composition of the light-emitting film included NPB (N,N′-bis(naphthalen-1-yl)-N,N′-bis(phenyl)-benzidine) and compound (PO-01-Bp-dipig)

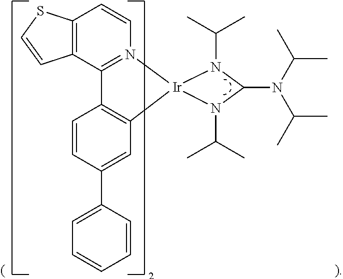

NPB and compound (PO-01-Bp-dipig) (the weight ratio between NPB and compound (PO-01-Bp-dipig) was 95:5) were dissolved in chlorobenzene to prepare the light-emitting film. Next, a TmPyPB (1,3,5-tri[(3-pyridyl)-phen-3-yl]benzene) layer (with a thickness of 55 nm, serving as a hole-block/electron-transport layer) was deposited on the light-emitting film. Next, a LiF layer (with a thickness of 1 nm) and an Al layer (with a thickness of 100 nm) were subsequently deposited on the TmPyPB film and packaged, obtaining the organic electroluminescent device (6). The structure of the organic electroluminescent device (6) is described in the following:

ITO (150 nm)/PEDOT:PSS (45 nm)/NPB: compound (PO-01-Bp-dipig) (30 nm)/TmPyPB (55 nm)/LiF (1 nm)/A1 (100 nm)

The optical properties including brightness (cd/m²), current efficiency (cd/A), power efficiency (1 m/W), emission wavelength (nm), and color coordinates (x, y) of the organic electroluminescent device (6) were measured and the results are described in Table 2.

### Comparative Example 1

### Preparation of the Organic Electroluminescent Device (7) (Dry Process)

A glass substrate with a patterned indium tin oxide (ITO) film of 150 nm was provided and then washed with a neutral cleaning agent, acetone, and ethanol with ultrasonic agitation. After drying the substrate with a nitrogen flow, the substrate was subjected to a UV/ozone treatment for 30 minutes. Next, PEDOT (poly(3,4)-ethylendioxythiophen) and PSS (e-polystyrenesulfonate) were selected to coat on the ITO film by a spin coating process (with a rotation rate of 2,000 rpm) to form a PEDOT:PSS film (with a thickness of 45 nm, serving as a hole injection layer). After heating to 130° C. for 10 min, a TAPC (di-[4-(N,N-ditolyl-amino)-phenyl]cyclohexane) layer (with a thickness of 35 nm), a TCTA (4,4′,4″-tris(carbazol-9-yl)triphenylamine) layer doped with commercial compound (Ir(phq)₂acac) (bis(2-phenylquinoline)(acetylacetonate)iridium(III)) (the ratio between TCTA and compound (Ir(phq)₂acac) was 100:6, with a thickness of 10 nm), a TmPyPB (1,3,5-tri[(3-pyridyl)-phen-3-yl]benzene) layer (with a thickness of 42 nm), a LiF layer (with a thickness of 0.5 nm), and an Al layer (with a thickness of 120 nm) were subsequently deposited on the ITO film under 10⁻⁶ torr and packaged, obtaining the organic electroluminescent device (7). The structure of the organic electroluminescent device (7) is described in the following:

ITO (150 nm)/TAPC (35 nm)/TCTA: compound (Ir(phq)₂acac) (6%, 10 nm)/TmPyPB (42 nm)/LiF (0.5 nm)/Al (120 nm)

The optical properties including brightness (cd/m²), current efficiency (cd/A), power efficiency (1 m/W), emission wavelength (nm), and color coordinates (x, y) of the organic electroluminescent device (7) were measured and the results are described in Table 2.

### Comparative Example 2

### Preparation of the Organic Electroluminescent Device (8) (Wet Process)

A glass substrate with a patterned indium tin oxide (ITO) film of 150 nm was provided and then washed with a neutral cleaning agent, acetone, and ethanol with ultrasonic agitation. After drying the substrate with a nitrogen flow, the substrate was subjected to a UV/ozone treatment for 30 minutes. Next, PEDOT (poly(3,4)-ethylendioxythiophen) and PSS (e-polystyrenesulfonate) were selected to coat on the ITO film by a spin coating process (with a rotation rate of 2,000 rpm) to form a PEDOT:PSS film (with a thickness of 45 nm, serving as a hole injection layer). After heating to 130° C. for 10 min, a light-emitting film (with a thickness of 30 nm) was formed on the PEDOT:PSS film by a spin coating process. The composition of the light-emitting film included TCTA (4,4′,4″-tris(carbazol-9-yl)triphenylamine) and compound (Ir(phq)₂acac) (bis(2-phenylquinoline)(acetylacetonate)iridium(III)). TCTA and compound (Ir(phq)₂acac) (the weight ratio between TCTA and compound (Ir(phq)₂acac) was 95:5) were dissolved in chlorobenzene to prepare the light-emitting film. Next, a TmPyPB (1,3,5-tri[(3-pyridyl)-phen-3-yl]benzene) layer (with a thickness of 45 nm, serving as a hole-block/electron-transport layer) was deposited on the light-emitting film. Next, a LiF layer (with a thickness of 1 nm) and an Al layer (with a thickness of 100 nm) were subsequently deposited on the TmPyPB film and packaged, obtaining the organic electroluminescent device (8). The structure of the organic electroluminescent device (8) is described in the following:

ITO (150 nm)/PEDOT:PSS (45 nm)/TCTA: compound (Ir(phq)₂acac) (30 nm)/TmPyPB (45 nm)/LiF (1 nm)/A1 (100 nm)

The optical properties including brightness (cd/m²), current efficiency (cd/A), power efficiency (1 m/W), emission wavelength (nm), and color coordinates (x, y) of the organic electroluminescent device (8) were measured and the results are described in Table 2.

TABLE 2

| | Organo- | | | Current | Power | Emission | |
|---|---|---|---|---|---|---|---|
| Examples/ | metallic | Voltage | Brightness | efficiency | efficiency | wavelength | CIE |
| Com. Examples | compounds | (V) | (cd/m²) | (cd/A) | (lm/W) | (nm) | (x, y) |
| Example 4 | PO-01-Bp | 5.4 | 1,000 | 35.5 | 20.7 | 580 | (0.55, 0.44) |
| Organic electro- | | | | | | | |
| luminescent | | | | | | | |
| device (1) | | | | | | | |
| Example 5 | PO-01-Bp- | 5.4 | 1,000 | 22.3 | 13.0 | 608 | (0.61, 0.38) |
| Organic electro- | dipba | | | | | | |
| luminescent | | | | | | | |
| device (2) | | | | | | | |
| Example 6 | PO-01-Bp- | 5.8 | 1,000 | 20.1 | 10.9 | 612 | (0.63, 0.36) |
| Organic electro- | dipig | | | | | | |
| luminescent | | | | | | | |
| device (3) | | | | | | | |
| Example 7 | PO-01-Bp | 4.1 | 1,000 | 18.6 | 14.3 | 576 | (0.54, 0.46) |
| Organic electro- | | | | | | | |
| luminescent | | | | | | | |
| device (4) | | | | | | | |
| Example 8 | PO-01-Bp- | 4.4 | 1,000 | 14.6 | 10.4 | 604 | (0.58, 0.40) |
| Organic electro- | dipba | | | | | | |
| luminescent | | | | | | | |
| device (5) | | | | | | | |
| Example 9 | PO-01-Bp- | 5.0 | 1,000 | 10.3 | 6.5 | 608 | (0.61, 0.38) |
| Organic electro- | dipig | | | | | | |
| luminescent | | | | | | | |
| device (6) | | | | | | | |
| Com. Example 1 | Ir(phq)₂acac | 4.4 | 1,000 | 16.7 | 11.9 | 604 | (0.62, 0.38) |
| Organic electro- | | | | | | | |
| luminescent | | | | | | | |
| device (7) | | | | | | | |
| Com. Example 2 | Ir(phq)₂acac | 4.3 | 1,000 | 16.5 | 12.1 | 596 | (0.60, 0.40) |
| Organic electro- | | | | | | | |
| luminescent | | | | | | | |
| device (8) | | | | | | | |

It will be apparent to those skilled in the art that various modifications and variations can be made to the disclosed embodiments. It is intended that the specification and examples be considered as exemplary only, with the true scope of the disclosure being indicated by the following claims and their equivalents.

What is claimed is:

1. An organometallic compound having formula (I) or (II), of: 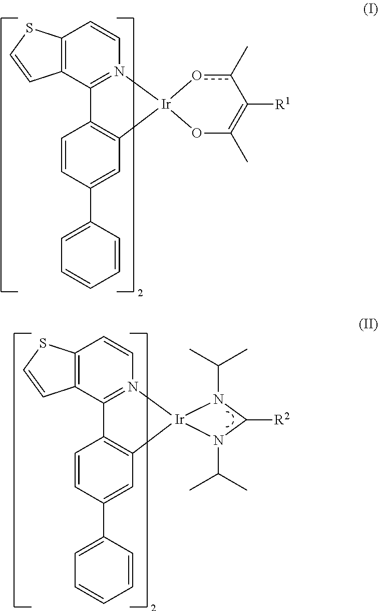
wherein, R¹, R² are hydrogen, phenyl, biphenyl, diisopropyl amino, or derivatives thereof.

2. The organometallic compound as claimed in claim 1, wherein the organometallic compound has formula (III), (IV) or (V), of:

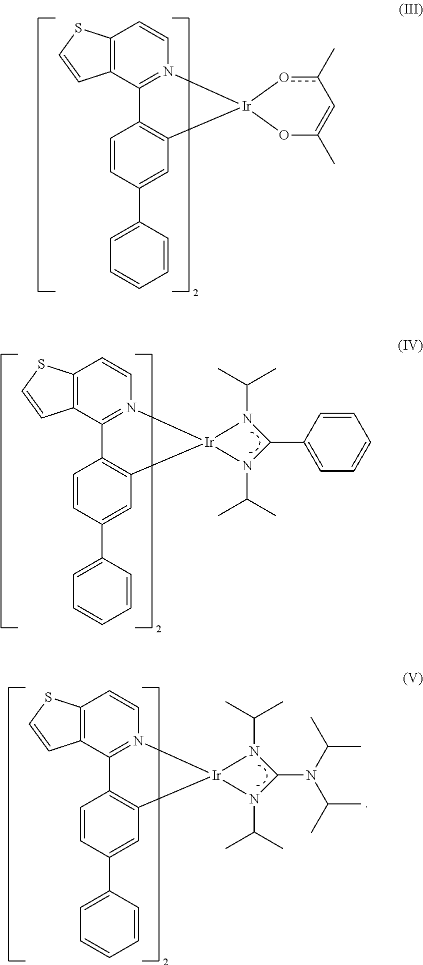

3. An organic electroluminescence device, comprising:
a pair of electrodes; and
an electroluminescent element disposed between the pair of electrodes, wherein the electroluminescent element comprises the organometallic compound as claimed in claim 1.

4. The organic electroluminescence device as claimed in claim 3, wherein the electroluminescent element emits reddish orange or red light under a bias voltage.

5. An organic electroluminescence device, comprising:
a pair of electrodes; and
an electroluminescent element disposed between the pair of electrodes, wherein the electroluminescent element comprises an emission layer which comprises a host material and a compound having the following formula (I) or (II) as a dopant material: 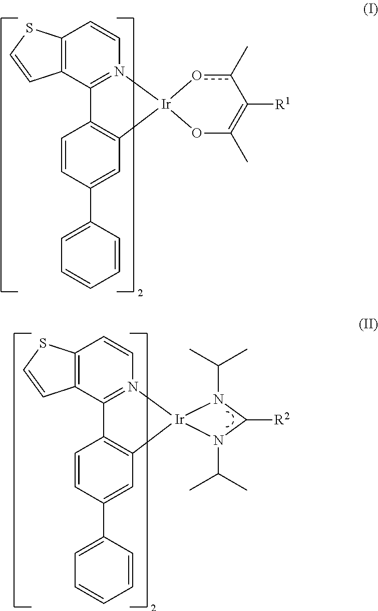
wherein, R¹, R² are hydrogen, phenyl, biphenyl, diisopropyl amino, or derivatives thereof.

6. The organic electroluminescence device as claimed in claim 5, wherein the electroluminescent element emits reddish orange or red light under a bias voltage.
